(19) United States
(12) Patent Application Publication
(10) Pub. No.: US 2007/0268664 A1
(43) Pub. Date: Nov. 22, 2007

(54) Power supply unit and cooling method

(75) Inventor: Toshiyuki Kobayashi, Inagi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignees: FUJITSU LIMITED, Kawasaki (JP); FUJITSU FRONTECH LIMITED, Inagi (JP)

(21) Appl. No.: 11/706,284

(22) Filed: Feb. 15, 2007

(30) Foreign Application Priority Data
May 16, 2006 (JP) 2006-136392

(51) Int. Cl. H05K 7/20

(52) U.S. Cl. 361/695

(57) ABSTRACT

A power supply unit, which comprises one or more power supply circuits generating an electric current and an air blower unit for forcibly generating airflow for cooling the power supply circuit, is covered by a cover. The adopted cover is one in which formed are an intake taking in the air for generating airflow by the air blower unit, a path for guiding the airflow exhausted from the power supply unit main body by the air blower unit by changing direction of the airflow to upward, and an outlet for externally exhausting the air flowing along the path. This configuration enables the exhaust of air in a desirable manner for the power supply unit or the place for putting the unit.

### BACKGROUND OF THE INVENTION

1. Field of the Invention

The present invention relates to a power supply unit prepared separately from an information processing apparatus for supplying the power to be supplied thereto.

2. Description of the Related Art

Heat is generated by consuming the electric power in electronic equipment. Because of this, it is a common practice to consider a countermeasure to a heat generation (i.e., cooling) in designing electronic equipment in which a thermal generation amount cannot be neglected. Electronic equipment premising a touching with a person places a good emphasis on suppressing a temperature rise to an extent that a person does not feel hot.

An air cooling method carrying out cooling by air is generally adopted for electronic equipment with a relatively small amount of heat generation. This is because the air cooling methods have advantages of a smaller number of parts, simpler structure, et cetera, as compared to adopting a liquid cooling method carrying out cooling by liquid.

The air cooling method is largely categorized into a natural convection cooling method utilizing convection generated by a density difference of air, and a forced convection cooling method generating convection by using a ventilator such as a blower and fan. The cases of adopting the forced convection method are increased recently with an increased heat generation amount with performance advances.

Some kinds of information processing apparatus, such as a POS (point of sales) terminal apparatus for example, premise a use in connection with other equipment. The POS terminal apparatus must be configured to be capable of supplying optional equipments, which are connected to the apparatus, with electric current. Because of this, a power supply unit becomes large for generating an operation-use electric current and the associated heat generation amount is relatively large. Consequently, some information processing apparatuses capable of being used as a POS terminal apparatus have a separate power supply unit, thereby suppressing a heat generation amount in the information processing apparatuses per se.

The air cooling system employs a frame equipped with holes (intake) for internally taking in the air for cooling, and holes (outlet) for externally exhausting the internal air. Dirt, dust, and the like can cause a shorting. Consequently, such an outlet is usually equipped on a side face of the frame in either case of employing a natural convection method or a forced convection method as noted in a Laid-Open Japanese Patent Application Publication No. 06-13775 (named as “patent document 1” hereinafter) and a Laid-Open Japanese Patent Application Publication No. 2003-86983 (named as “patent document 2” hereinafter). The equipping an outlet noted above attempts to reduce an accumulation of dust, dirt and the like in the inside of an apparatus.

The equipping an outlet on a side of the frame exhausts the air warmed by heat transfer from the side in the direction of perpendicular to the side surface. Accordingly, if a body large enough to hamper an air flow is placed nearby the side, an exhaust efficiency of the air is reduced and a decreased cooling efficiency associated with the reduced airflow ushers in a temperature rise. Because of this, it is impossible to place a large body nearby the outlet, making an installation largely restricted. Therefore, lessening the restriction is considered to be important in order to utilize a space efficiently.

### SUMMARY OF THE INVENTION

The purpose of the present invention is to provide a power supply unit allowing an installation of an object close to an outlet of air.

A power supply unit according to the present invention is one, being prepared separately from an information processing apparatus, for supplying the information processing apparatus, e.g., one capable of being utilized as a POS terminal apparatus, with an electric current required thereby, comprises a power supply unit main body comprising one or more power supply circuits for generating the current and an air blower unit for forcibly generating air flow for cooling the power supply circuit; and a cover, covering the power supply unit main body, in which formed are an intake taking in the air for generating airflow by means of the air blower unit, a path for guiding the airflow exhausted from the power supply unit main body by the air blower unit by changing direction of the airflow to upward, and an outlet for externally exhausting the air flowing along the path.

Note that a desirable configuration of the cover is constituted by plural number of parts, and the path and outlet are formed by making a space between at least two parts. And one of the at least two parts is desirably configured to remove by utilizing the outlet formed by the space. Also, the cover is desirably configured to have a space for passing a cable connecting to the information processing apparatus.

A method for cooling a power supply unit according to the present invention is one for cooling the power supply unit, being prepared separately from an information processing apparatus, for supplying the information processing apparatus, e.g., one capable of being utilized as a POS terminal apparatus, with an electric current required thereby, comprises: preparing a power supply unit main body comprising one or more power supply circuits for generating the current and an air blower unit for forcibly generating airflow for cooling the power supply circuit; preparing a cover for covering the power supply unit main body; and by cover, managing an intake of air for generating airflow by the air blower unit, an orientation of externally exhausting air passed the power supply unit main body by the air blower unit, and a position of the exhaust of the air, and performing the cooling.

According to the present invention, a power supply unit, which comprises one or more power supply circuits (at least one power supply circuit) generating an electric current and an air blower unit for forcibly generating airflow for cooling the power supply circuit, is covered by a cover. The adopted cover is one in which formed are an intake taking in the air for generating airflow by the air blower unit, a path for guiding the airflow exhausted from the power supply unit main body by the air blower unit by changing direction of the airflow to upward, and an outlet for externally exhausting the air flowing along the path.

The adoption of such a cover enables cooling by having the cover manage an intake of air for generating an airflow by means of the air blower unit, an orientation of externally exhausting the air passed the power supply unit main body by the air blower unit, and a position of the exhaust of the air. This configuration enables the exhaust of the air in a desirable manner for the power supply unit or the place for putting the unit. An influence of dust dirt and the like invading from the outlet can be avoided or reduced by a path for changing the orientation of airflow. It is possible to prevent or reduce an invasion of dust dirt and the like into the power supply unit main body. Owing to these effects, a power supply unit allowing an installation of object(s) close to the outlet of the air can easily be accomplished. The accomplishment of such a power supply unit makes it possible to utilize a space for installing the power supply unit more effectively.

### BRIEF DESCRIPTION OF THE DRAWINGS

FIG. 1A is a diagonal front view showing an external appearance of a POS system built up by using a power supply unit according to the present embodiment;

FIG. 1B is a diagonal rear view showing an external appearance of a POS system built up by using a power supply unit according to the present embodiment;

FIG. 2 is a diagram describing a comprisal of a buildable POS system;

FIG. 3 is a diagonal perspective diagram of a power supply unit 120 according to the present embodiment;

FIG. 4 is a diagonal explosion diagram of the power supply unit 120 according to the present embodiment;

FIG. 5 is a diagram describing a method for connecting option equipment to an information processing apparatus 110 usable as a POS terminal apparatus;

FIG. 6 is a diagram describing a space for accommodating a cable 501 prepared internally in the power supply unit 120 according to the present embodiment;

FIG. 7 is a diagonal view diagram of the power supply unit 120 with a cover member 320 being removed; and

FIG. 8 is an enlarged diagram of the part C indicated in FIG. 7.

### DESCRIPTION OF THE PREFERRED EMBODIMENTS

The following is a detailed description of the preferred embodiment of the present invention by referring to the accompanying drawings.

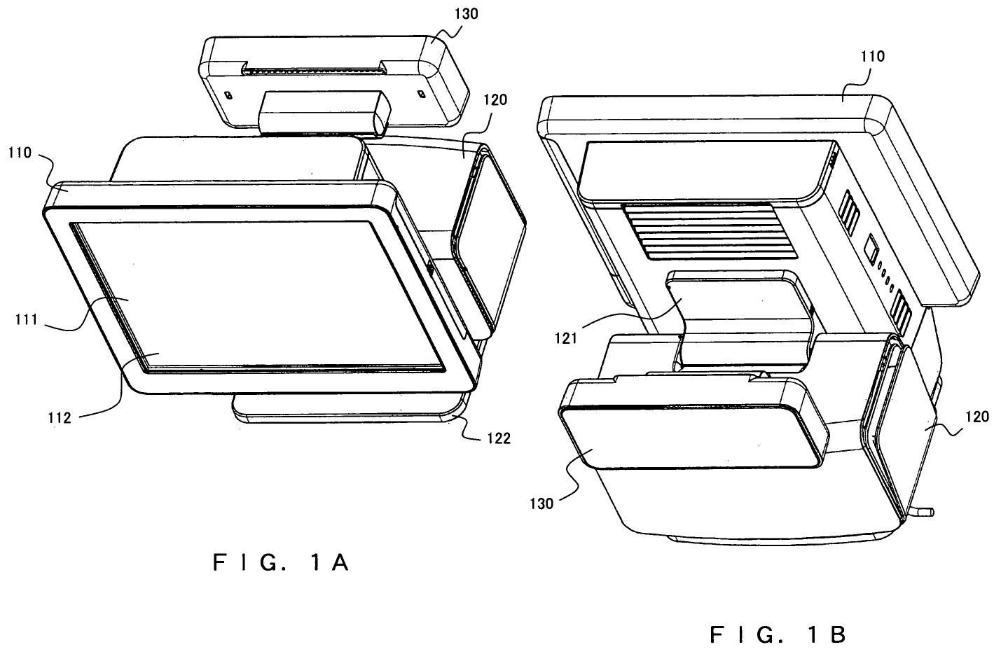

FIGS. 1A and 1B are diagonal views of an external appearance of a POS system built up by using a power supply unit according to the present embodiment; with FIG. 1A showing a diagonal front view, and FIG. 1B showing a diagonal rear view.

The power supply unit 120 is for supplying an information processing apparatus 110 usable as a POS terminal apparatus and is implemented as a separate apparatus from the information processing apparatus 110. In FIGS. 1A and 1B, a mounting unit 121 is one for mounting the information processing apparatus 110 onto the power supply unit 120, and a customer display 130 is one for displaying information to be transmitted to a customer. The power supply unit 120 allows a mounting of the customer display 130 in addition to that of the information processing apparatus 110.

The above noted front side is defined as the side for mounting the information processing apparatus 110, and the rear side is the reverse side. The power supply unit 120 is equipped with a support board 122 having a wide bottom so as to place the power supply unit 120 stably. Accordingly the power supply unit 120 is configured to premise a use in a state of the bottom surface of the support board 122 being placed on a level or approximate level surface. The following description is provided by premising such a usage condition unless otherwise noted herein.

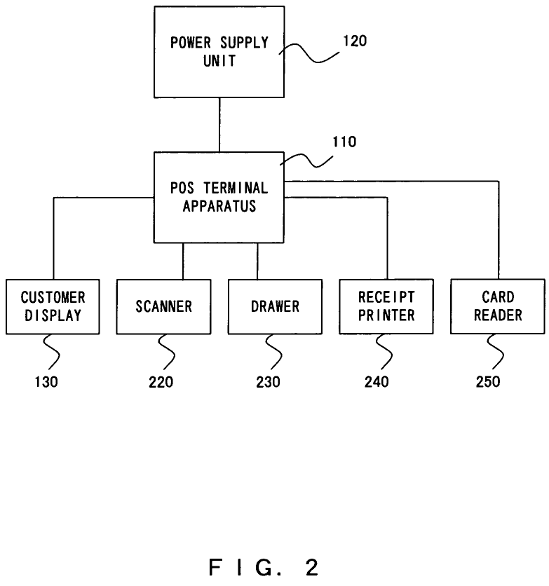

The information processing apparatus (noted as “POS terminal” hereinafter) 110 is of a tablet form comprising a display apparatus 111 and a touch panel 112 featured on the entire surface thereof. The POS terminal 110 is configured to enable connections of a scanner 220, a drawer 230, a receipt printer 240 and a card reader 250 as optional equipment as shown in FIG. 2, in addition to the connection of the customer display 130 shown in FIGS. 1A and 1B. By this, the POS system is built up by connecting a necessary unit from among the aforementioned pieces of optional equipment to the POS terminal 110. The power supply unit 120 is usually placed on the drawer 230.

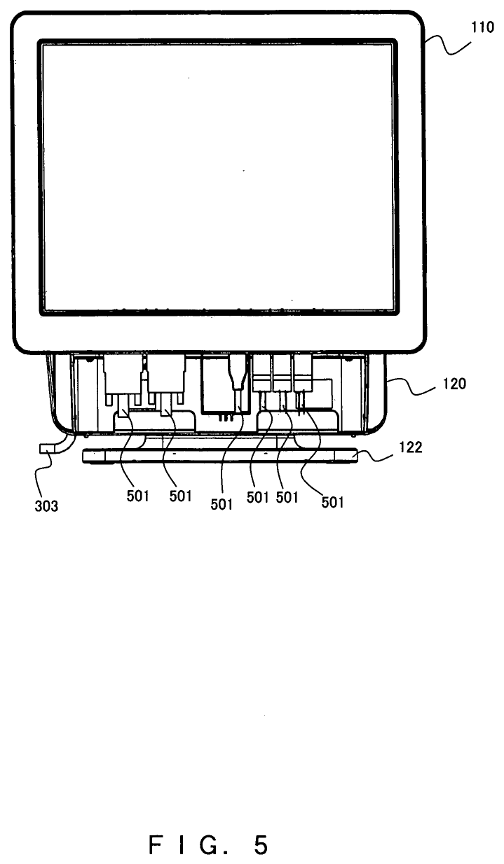

Each interface for connecting the optional equipment is placed under the display apparatus 111 as shown in FIG. 5. By this configuration, a connection of the optional equipment is achieved by mounting a connector attached to a cable 501 for connecting the individual optional equipment.

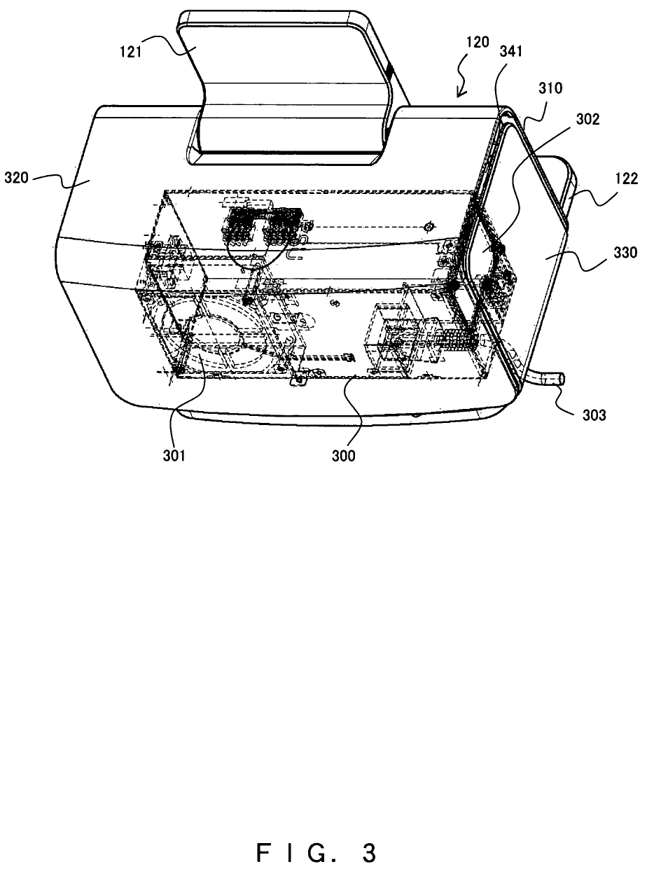

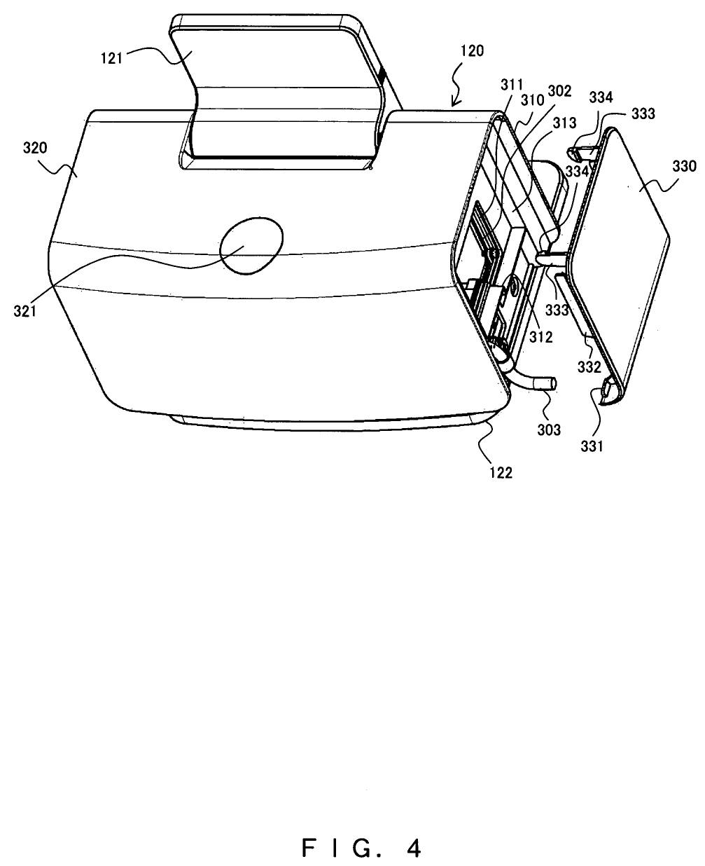

FIG. 3 is a diagonal perspective diagram of the power supply unit 120 according to the present embodiment; and FIG. 4 is a diagonal explosion diagram thereof.

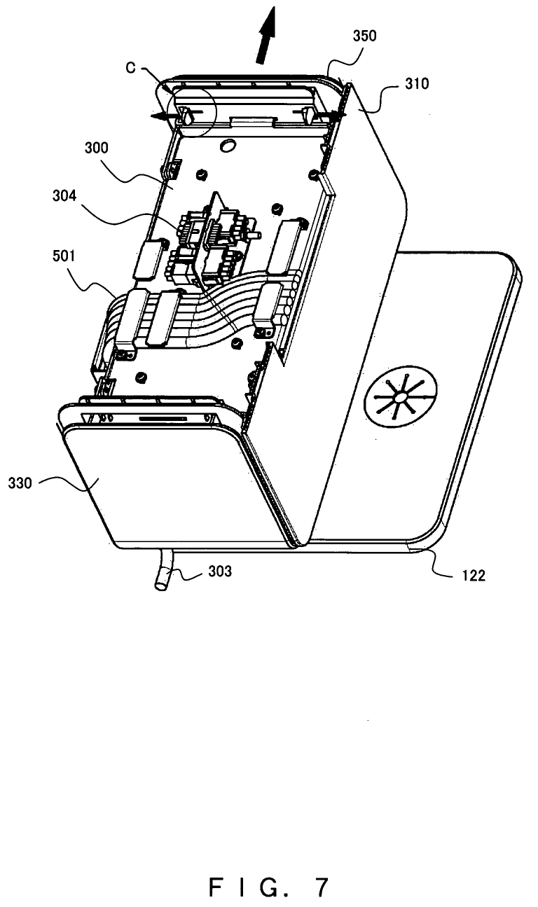

The power supply unit 120 is a power supply unit main body 300 covered by a cover. The numerical 310, 320 and 330 shown in FIG. 3 are cover parts constituting the cover. The cover parts additionally includes the object attaching numerical 350 shown in FIG. 7. The cover parts 330 and 350 are mounted on the side face of the cover part 310 as shown in FIG. 7. The cover part 320 covering the top and rear faces of the power supply unit main body 300 is also mounted onto the cover part 310.

In addition to plural number of power supply circuits, a fan 301, as a ventilator for cooling each power supply circuit, is mounted onto the power supply unit main body (noted as “main body” hereinafter) 300. The fan 301 is mounted at an end of the main body 300, and the configuration is also such that the air, which is taken in internally to the cover part 320 from the nearby gap between the cover part 320 and support board 122 by the fan 301 at the end, is exhausted from a hole 302 featured at the end of the main body 300. The numerical 303 shown in FIG. 3 is a power cord for inputting the current from an external power supply such as an electric point, et cetera. The main body 300 can be furnished with a battery for making it operable at the time of a power outage.

The cover part 310 is featured with a hole 311 at the position of the hole 302 of the main body 300 and also matching with the form of the hole 302 as shown in FIG. 4. The cover part 330, which is mounted on the side face where the hole is featured, is featured with two protrusions 331 (although FIG. 4 shows only one of the two) at the lower parts of the cover part 330, and two protrusions 333, which respectively comprise protrusion parts 334, at the upper parts of the cover part 330. The side face in which the hole 311 is featured is equipped with holes capable of accepting these protrusions 331 and 333. By this, a mounting of the cover part 330 onto the cover part 310 is to insert the two protrusions 331 into the respective corresponding holes, followed by rotating the cover part 330 around these protrusions 331 as the axis so as to insert the two protrusions 333 into the respective corresponding holes.

A hole is featured in the cover part 320. The numerical 321 shown in FIG. 4 is a member for covering the hole. The customer display 130 is mounted after the member 321 is removed.

The circumference, except for the top part of the hole 311 of the cover part 310 is featured with wall-like projection parts including projections 312 and 313. The cover part 330, which is to be mounted onto the side face featured with the hole 311, is also featured with wall-like projection parts including a projection part 332. These projection parts, particularly the projection part 332, are featured for maintaining the relative positional relationship between the cover parts 310 and 330. These features are the same for the cover member 350.

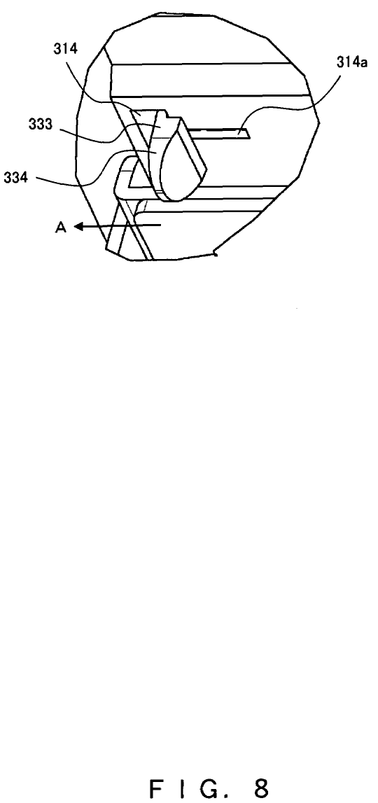

FIG. 8 is an enlarged diagram of the part C indicated in FIG. 7. At this point, a description is on a specific reason why the relative positional relationship between the cover parts 310 and 330 can be maintained, by referring to FIG. 8.

The part C is an internal circumference part of a hole 314 featured in the upper part of the side face for mounting the cover part 350. The cover parts 330 and 350 are basically the same configuration, including the mounting method. Therefore, marks shown in FIG. 4 are conveniently attached in the enlarged diagram of the part C, and the description is provided by premising the cover part 350 as the cover part 330.

A side face of the protrusion part 334, which is featured toward the end of the protrusion 333, facing the cover part 330 is parallel, or approximately parallel, with the inside surface of the cover part 310 as shown in FIG. 8. The cover part 330 is produced such that the distance between the two protrusion parts 334 is shorter than that between the two holes 314 featured in the cover part 310. Because of this, when the protrusion part 334 is inserted into the hole 314, the protrusion 333 automatically moves the protrusion part 334 toward the inside of the hole 314 (i.e., toward the other protrusion 333 in this event). This movement results in a state shifting as shown in FIG. 8. In order to enable the shift, the cover part 330 (and 350) is produced by a material having elasticity, e.g., plastics.

In the state shown in FIG. 8, the inside surface of the protrusion part 334 is meshing with the cover part 310. Therefore, the protrusion part 334 cannot be extracted from the hole 314 if it is pulled to separate from the cover part 310, thus unable to remove the cover part 330. This configuration prevents a third party from removing the cover part 330 easily.

The distance of the cover part 310 from the cover part 330 in the direction of separating the former from the latter is limited by the protrusion part 334. As the protrusion part 334 hits the cover part 310, it is no longer possible to further separate the cover part 330. The protrusion part 334, however, cannot limit the distance in the direction of pushing the cover part 330 further in. Because of this, the projection part 332 is featured for limiting the distance in the direction of pushing in the cover part 330. Thus, the range of moving the cover part 330 is limited by the protrusion part 334 and projection part 332. Therefore, the relative positional relationship between the cover parts 310 and 330 is always maintained appropriately.

The hole 314 is featured as the letter “T” as shown in FIG. 8. FIG. 8 is a diagram showing a state of the protrusion part 334 fitting with the hole 314. It is enabled for moving (i.e., retracting) the protrusion part 334 in the direction of the arrow A shown in FIG. 8, which is toward the outside, by inserting a plate member insertable into the insertion hole (that is noted as “unlatching-use member” hereinafter) 314a, which is the vertical line of the letter T and the empty part of the hole 314. Thus moving the protrusion part 334 in the direction of the arrow A unlatches the fit between the protrusion part 334 and hole 314, making it possible to extract the former from the latter. The reference technical documents include Laid-Open Japanese Patent Application Publication Nos. 05-55264 and 08-258631.

There is an exhaust-use gap 341 between the upper part of the cover parts 310 and 330 as shown in FIG. 3. The unlatching-use member is inserted into the hole 314 from the gap 341 in the horizontal direction relative to the hole 314 to be able to unlatch the fitting between the protrusion part 334 and hole 314, which configuration makes it difficult to visualize a specification for assembly of the cover when viewed from the front, and at the same time makes it possible to remove the cover part 330 quickly. This configuration enables an easy mounting and replacement of the cord 303 for connecting to the power source.

The air exhausted from the hole 302 of the main body 300 goes through the hole 311 and flows between the cover parts 310 and 320. The reason for maintaining the relative positional relationship between the cover parts 310 and 330 always appropriate is also for always performing the external exhaust of the air appropriately. The cover part 310, which features the projection part including the projection parts 312 and 313 on the circumference of the hole 311 except for the upper part thereof, and the cover part 330, which features the projection part 332, together accomplish the path for changing direction of the airflow exhausted from the main body 300 to the upward and guide it, and the gap 341 which functions as the exhaust opening of the air.

The air is exhausted upward from the gap 341 because the orientation of the airflow is changed to the upward by means of the path. Thus exhausting the air upward makes it possible to put object(s) close to the side of the cover part 330 or install the apparatus per se in the state of the part member 330 touching a wall, et cetera. It is also possible to put object(s) in the rear part of the cover part 320 or install the apparatus with the rear part of the cover part 320 touching a wall, et cetera. This makes it possible to utilize spaces for putting object(s) and installing the apparatus more efficiently.

At the time of using the power supply unit 120, a possibility of dust, dirt and the like, invading the inside from the gap 341 is avoided because the air is exhausted therefrom. Although there is a possibility of dust, dirt and the like, invading from the gap 341 at the time of not using the unit 120, there is only a low possibility of such invasion into the inside of the main body 300 because it is positioned toward the rear side from the path formed between the cover parts 310 and 330 in the horizontal direction. Even though dust, dirt and the like, invade, all of those or most thereof are externally exhausted by the air forcibly generated by the fan 301 at the time of using the unit 120. Actually, it is rarely left unused for an extended time period. Therefore, it is practically possible to avoid an influence of dust, dirt and the like, reliably.

The path and outlet (i.e., the gap 341) formed by the two different cover parts 310 and 330 can be implemented by one or more pieces of exclusive part. In the case of preparing an exclusive part, however, a complex form path makes it difficult to produce and requires a readiness of a plurality of exclusive part. Also required are parts for mounting the exclusive part, and those mounting parts must be configured to be capable of mounting the exclusive part. Therefore, the number of parts is increased, and the production cost is risen.

Comparably, in the case of forming the path and outlet by two different cover parts 310 and 330, these are produced separately, thereby making it possible to respond if the path is in a complex form. Besides, there is fundamentally no necessity of considering any parts other than these. Due to these reasons, it is possible to suppress the number of parts as compared to preparing exclusive part(s). The reduction on the number of parts suppresses a production cost.

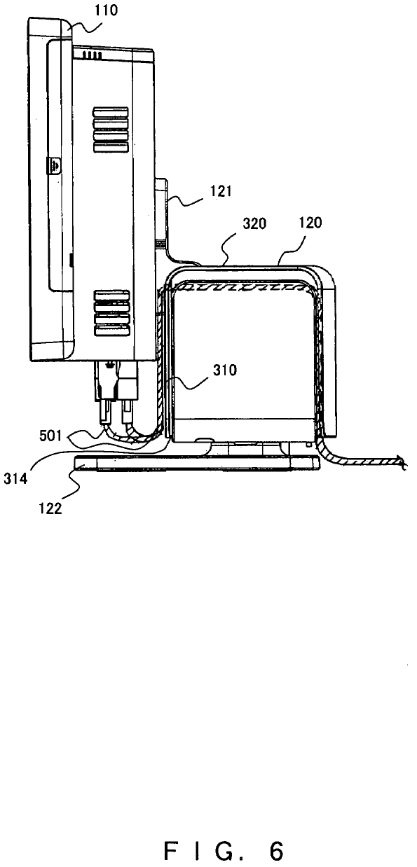

As shown in FIG. 2 or FIG. 5, a plurality of optional equipment can be connected to the POS terminal 110. Proportionately with the number of optional equipment to be connected, a larger space is required for passing the cables 501, resulting in hampering an effective utilization of the space. Considering this, the present embodiment is configured to furnish the inside of the power supply unit with a space for passing the cables 501. The configuration enables an accommodation of the cables 501 in the lower part between the mounting part 121 and cover part 320, and in the inside of the cover part 320, as shown in FIG. 6. The accommodation is carried out by guiding the cables 501 along the casing of the main body 300 as shown in FIG. 7. This configuration enables a connection to optional equipment by way of the cables 501 by utilizing the space provided in the rear of the power supply unit 120 by hardly using the space existing on the front side thereof. The reason for positively utilizing the space existing in the rear is that the space is unsuitable as a place for putting object(s) because of the POS terminal 110 and power supply unit 120. In other words, it is because a space for putting object(s) can be utilized more effectively by positively using the space existing in the rear.

Note that the present embodiment is configured to guide the air exhausted from the hole 302 of the main body 300; it may, however, alternatively be configured to guide it in a plurality of directions, including a downward direction for example. In any event, it is necessary to determine a direction for guiding the air by the position of an intake for taking in the air for generating a forced airflow by means of the fan 301.

The present embodiment is configured to equip the bottom part 314 of the cover part 310, shown in FIG. 6, with the intake. In the case of equipping the intake in the bottom part 314, an exhaust of the air downward makes it easy to take in the exhausted air from the intake. Thus taking in the air causes the overall temperature of the intake air to rise, resulting in reducing the cooling efficiency. This is the reason for a necessity of considering the position of the intake.

What is claimed is:

1. A power supply unit, being prepared separately from an information processing apparatus, for supplying the information processing apparatus with an electric current required thereby, comprising:
a power supply unit main body comprising one or more power supply circuits for generating the electric current and an air blower unit for forcibly generating air flow for cooling the power supply circuit; and
a cover, covering the power supply unit main body, in which formed are an intake taking in air for generating airflow by the air blower unit, a path for guiding the airflow exhausted from the power supply unit main body by the air blower unit by changing direction of the airflow to upward, and an outlet for externally exhausting the air flowing along the path.

2. The power supply unit according to claim 1, wherein
said cover is constituted by plural number of parts, and said path and outlet are formed by making a space between at least two parts.

3. The power supply unit according to claim 2, wherein
one of said at least two parts is configured to remove by utilizing said outlet formed by said space.

4. The power supply unit according to claim 1, wherein
said cover is configured to have a space for passing a cable connecting to said information processing apparatus.

5. A method for cooling a power supply unit, being prepared separately from an information processing apparatus, for supplying the information processing apparatus with an electric current required thereby, comprising:
preparing a power supply unit main body comprising one or more power supply circuits for generating the electric current and an air blower unit for forcibly generating airflow for cooling the power supply circuit;
preparing a cover for covering the power supply unit main body; and
by cover, managing an intake of air for generating airflow by the air blower unit, an orientation of externally exhausting air passed the power supply unit main body by the air blower unit, and a position of the exhaust of the air, and performing the cooling.
